(19) United States
(12) Patent Application Publication
(10) Pub. No.: US 2007/0204088 A1
(43) Pub. Date: Aug. 30, 2007

(54) Modularized circuit board bus connection control method and system

(75) Inventor: Kun-Fu Chen, Taipei (TW)

Correspondence Address: EDWARDS ANGELL PALMER & DODGE LLP, P.O. BOX 55874, BOSTON, MA, 02205, US

(73) Assignee: Inventec Corporation, Taipei (TW)

(21) Appl. No.: 11/363,655

(22) Filed: Feb. 27, 2006

(51) Int. Cl. G06F 13/00; H05K 7/10

(52) U.S. Cl. 710/301

(57) ABSTRACT

A modularized circuit board bus connection control method and system is proposed, which is designed for use with a computer platform, such as a blade server, for providing a bus connection control function when connected to a modularized circuit board, such as a server module; which is characterized by the capability of using an enable signal activating voltage from a built-in enablement setting circuit in the blade server for bus connection control, such that if the server module is well electrically connected to the blade server, the bus will be switched to a connected state; and otherwise, if poorly connected, the bus will be maintained in the disconnected state to isolate the server module from the blade server. This feature can help prevent the blade server to waste much time and system resource in handling the condition of poor electrical connection and thus ensure the overall system performance.

### BACKGROUND OF THE INVENTION

1. Field of the Invention

This invention relates to computer technology, and more particularly, to a modularized circuit board bus connection control method and system which is designed for use in conjunction with a computer platform that can be installed with one or more modularized circuit boards, such as a blade server installable with multiple server modules, for providing the blade server with a modularized circuit board bus connection control function that can be activated when a server module is being attached to the chassis of the blade server for the purpose of allowing the server module to be functionally linked to the blade server only under the condition that a reliable electrical connection is established therebetween (i.e., all the electrical contact points between the server module and the blade server are in good electrical connection).

2. Description of Related Art

A blade server is a clustering type of network server that is characterized by the use of a chassis to integrate a cluster of server modules (commonly called “blades”), with all of these server modules providing the same server functionality. In other words, a blade server can respond to a client's request by linking any one of the clustered server modules to the client. In practical implementation, each server module is made into a single circuit board (i.e., blade), which can be easily fitted to the blade server's enclosure to increase the blade server's client serving capacity. Moreover, a blade server is typically equipped with a common management control module for controlling all the operations of the multiple server modules and their shared resources in the blade server.

I2C (Inter-Integrated Circuit) is a standard of bus architecture which is commonly utilized by blade servers to provide a connecting interface between the blade server's chassis management unit and each server module for data exchange therebetween. In practice, a hot swappable bus buffer is typically provided between the blade server and each server module to buffer the data flowing therebetween.

One drawback to the above-mentioned bus architecture in practical applications, however, is that if the server module is plugged to the backplane of the blade server with a poor condition of electrical connection (i.e., there exists some pins in the connector of the server module that are in poor electrical contact with the backplane of the blade server after being plugged), then the chassis management unit of the blade server will detect such a condition and repeatedly issue an interrupt message to request for the resolving of this condition. This action, however, would cause the chassis management unit of the blade server to waste much time and system resource in the handling of this condition, thus undesirably degrading the overall system performance.

### SUMMARY OF THE INVENTION

It is therefore an objective of this invention to provide a modularized circuit board bus connection control method and system which allows a bus used to interconnect the server module with the server module to be switched into a connected state only under the condition that a reliable electrical connection has been established between the server module and the blade server, so that it can help prevent the chassis management unit of the blade server to waste much time and system resource in the handling of the condition of poor electrical connection and thus to ensure the overall system performance of the blade server.

The modularized circuit board bus connection control method and system according to the invention is designed for use in conjunction with a computer platform that can be installed with one or more modularized circuit boards, such as a blade server installable with multiple server modules, for providing the blade server with a modularized circuit board bus connection control function that can be activated when a server module is being attached to the chassis of the blade server for the purpose of allowing the server module to be functionally linked to the blade server only under the condition that a reliable electrical connection is established therebetween.

The modularized circuit board bus connection control method according to the invention comprises: (1) in an event of the modularized circuit board being plugged to the computer platform, detecting whether a built-in enablement setting circuit in the computer platform has set an enablement signal to true value in response to the condition that the plugging of the modularized circuit board to the computer platform has established an electrical coupling therebetween; and if YES, capable of issuing a link enable message; and (2) responding to the link enable message by switching the bus into a connected state for functionally linking the modularized circuit board to the computer platform.

In architecture, the modularized circuit board bus connection control system according to the invention comprises: (A) a detection module, which is capable of being activated in response to an event of the modularized circuit board being plugged to the computer platform, and which is capable of detecting whether a built-in enablement setting circuit in the computer platform has set an enablement signal to true value in the condition that the plugging of the modularized circuit board to the computer platform has established an electrical coupling therebetween; and if YES, capable of issuing a link enable message; and (B) a switching module, which is connected at a breakpoint in the bus used to interconnect the modularized circuit board with the computer platform, and which is initially set to disconnect the bus and capable of responding to the link enable message from the detection module by switching the bus into a connected state for functionally linking the modularized circuit board to the computer platform.

The modularized circuit board bus connection control method and system according to the invention is characterized by the capability of fetching an enable signal activating voltage from a built-in enablement setting circuit in the blade server for controlling the connection and disconnection of a bus used to interconnect the server module with the blade server, such that if the server module is well electrically connected to the blade server, the bus will be switched to a connected state to functionally link the server module to the blade server; and otherwise, if poorly connected, the bus will be maintained in the disconnected state such that the server module is functionally isolated from the blade server. This feature can help prevent the chassis management unit of the blade server to waste much time and system resource in the handling of the condition of poor electrical connection and thus to ensure the overall system performance of the blade server.

### BRIEF DESCRIPTION OF DRAWINGS

The invention can be more fully understood by reading the following detailed description of the preferred embodiments, with reference made to the accompanying drawings, wherein:

FIG. 1 is a schematic diagram showing the application of the modularized circuit board bus connection control system according to the invention with a blade server; and

FIG. 2 is a schematic diagram showing the internal architecture of the modularized circuit board bus connection control system of the invention.

### DETAILED DESCRIPTION OF PREFERRED EMBODIMENTS

The modularized circuit board bus connection control method and system according to the invention is disclosed in full details by way of preferred embodiments in the following with reference to the accompanying drawings.

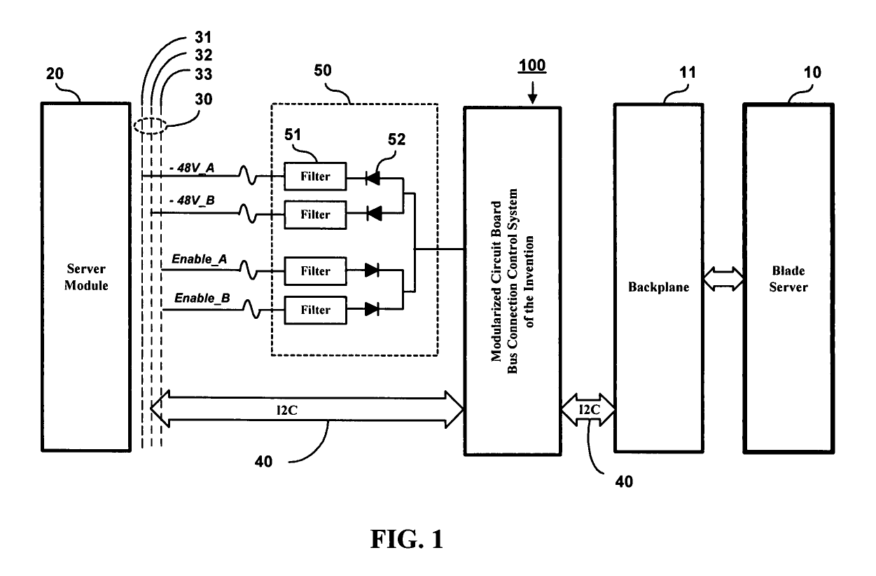

FIG. 1 is a schematic diagram showing the application of the modularized circuit board bus connection control system according to the invention (as the block indicated by the reference numeral 100). As shown, the modularized circuit board bus connection control system of the invention 100 is designed for use in conjunction with a computer platform, such as a blade server 10, particularly an ATCA (Advanced Telecom Computing Architecture) compliant blade server, that is connectable via a bus 40 with one or more modularized circuit boards, such as server modules 20. In actual operation, the modularized circuit board bus connection control system of the invention 100 is capable of providing the blade server 10 with a modularized circuit board bus connection control function that can be activated when a server module 20 is being plugged to the backplane 11 of the blade server 10, and when activated, is capable of switching the bus 40 into a connected state for functionally linking the server module 20 to the blade server 10 only under the condition that a reliable electrical connection has been established between the server module 20 and the blade server 10. In other words, if the plugging of the server module 20 to the blade server 10 involves poor condition of electrical connections at any of the connecting pins of the connector 30, then the bus 40 will remain in a disconnected state.

In practical implementation, for example, the bus 40 is based on an I2C (Inter-Integrated Circuit) compliant bus architecture. In the case of the blade server 10 being ATCA-compliant, the server module 20 is equipped based on the ATCA standard with a connector 30 that is specifically provided with a group of large-length pins 31, a group of intermediate-length pins 32, and a group of small-length pins 33; wherein the large-length pins 31 include a power pin denoted by “−48V_A”, the intermediate-length pins 32 include a power pin denoted by “−48V_B”, and the small-length pins 33 include a pair of enable pins denoted respectively by “Enable_A” and “Enable_B”. The I2C bus 40 is used for connection with the intermediate-length pins 32. Moreover, based on the ATCA standard, the blade server 10 is specifically equipped with a built-in enablement setting circuit 50, which is composed of a group of filters 51 and a group of diodes 52 as shown in FIG. 1. In the condition that the connector 30 of the server module 20 is plugged to the backplane 11 with good condition of electrical connections (i.e., all the pins 31, 32, 33 of the connector 30 are well electrically connected to the backplane 11), then the “−48V_A” and “−48V_B” pins of the connector 30 will responsively output a −48V voltage to the enablement setting circuit 50, causing the enablement setting circuit 50 to set the “Enable_A” and “Enable_B” pins to logic-HIGH voltage states (i.e., true value in logic state). When the “Enable_A” and “Enable_B” pins are set to logic-HIGH voltage state, it represents that the server module 20 is well electrically connected to the backplane 11. The modularized circuit board bus connection control system of the invention 100 is designed to utilize the “Enable_A” and “Enable_B” signals from the enablement setting circuit 50 to provide the I2C bus 40 with a connection control function.

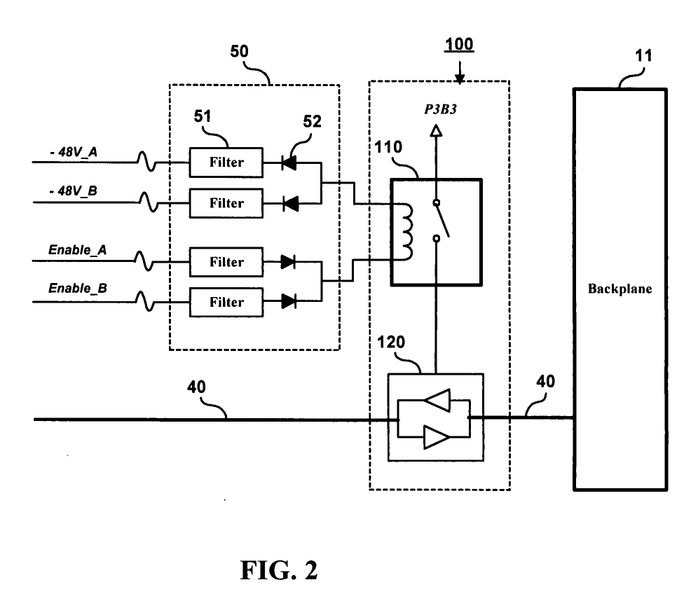

As shown in FIG. 2, the modularized circuit board bus connection control system of the invention 100 comprises: (A) a detection module 110; and (B) a switching module 120. The respective attributes and behaviors of the constituent modules 110, 120 of the modularized circuit board bus connection control system of the invention 100 are described in details in the following.

The detection module 110 is capable of being activated in response to an event of the server module 20 being plugged to the blade server 10, and which is capable of detecting whether the built-in enablement setting circuit 50 of the blade server 10 has set the “Enable_A” and “Enable_B” signals to true values (i.e., logic-HIGH voltage states). If NO, the detection module 110 will issue no link enable message; and whereas if YES, the detection module 110 will responsively issue a link enable message to the switching module 120. In practical implementation, for example, the detection module 110 is a relay as shown in FIG. 2, which is connected to the enablement setting circuit 50 to be controlled by the “−48V_A” and “−48V_B” signals from the connector 30 of the server module 20 to selectively switch the connection of a system voltage (denoted by P3B3) to the switching module 120; i.e., the relay (detection module 110) is initially set to disconnect the P3B3 system voltage from the switching module 120, and in the event that the “−48V_A” and “−48V B” signals are active, it will actuate the relay (detection module 110) to connect the P3B3 system voltage to the switching module 120. The P3B3 system voltage supplied to the switching module 120 is therefore used to implement the above-mentioned link enable message. Beside the relay, there exists many other various different ways to implement the detection module 110.

The switching module 120 is connected at a breakpoint in the I2C bus 40 for controlling the connection and disconnection of the I2C bus 40 (note that in FIG. 2, only one line in the I2C bus 40 is shown for demonstration; and in practice, each line in the I2C bus 40 is connected with one switching module 120). The switching module 120 is initially set to disconnect the I2C bus 40 and capable of responding to the link enable message from the detection module 110 by switching the I2C bus 40 into a connected state for functionally linking the server module 20 to the blade server 10 (i.e., allowing the server module 20 and the blade server 10 to exchange data). In practice, for example, a transmission gate device is used to implement the switching module 120, which is capable of being switched into an electrically-conductive state in response to the link enable message (i.e., the P3B3 system voltage) and thereby switching the I2C bus 40 into a connected state.

The following is a detailed description of a practical example of the application of the modularized circuit board bus connection control system of the invention 100 during actual operation.

Referring to FIG. 1 together with FIG. 2, in actual operation, when the blade server 10 needs to increase its service capacity, the system management personnel can plug an additional server module 20 to the backplane 11 of the blade server 10. If the connector 30 of the server module 20 is well electrically connected to the backplane 11, it will cause the server module 20 to output a −48V voltage via the “−48V_A” and “−48V_B” pins of the connector 30 to the enablement setting circuit 50, causing the enablement setting circuit 50 to set the “Enable_A” and “Enable_B” pins to logic-HIGH voltage states. Otherwise, if poorly connected (i.e., no electrical connection is established), then the server module 20 will output no −48V voltage to the enablement setting circuit 50. In the event that the server module 20 outputs a −48V voltage to the enablement setting circuit 50, it will cause the detection module 110 to respond by issuing a link enable message to the switching module 120 (i.e., in the case of the detection module 110 being a relay, the −48V voltage will cause the relay to be closed and thus connect the P3B3 system voltage to the switching module 120). In the event of no link enable message from the detection module 110, the switching module 120 maintains the I2C bus 40 in a disconnected state; and whereas in the event of a link enable message from the detection module 110, the switching module 120 responds by switching the I2C bus 40 to a connected state, thereby functionally linking the server module 20 to the blade server 10. In other words, if the connector 30 of the server module 20 is well electrically connected to the backplane 11 of the blade server 10, the modularized circuit board bus connection control system of the invention 100 will responsively cause the I2C bus 40 to be switched to a connected state to functionally link the server module 20 to the blade server 10; otherwise, if poorly connected, the I2C bus 40 will be maintained in the disconnected state such that the server module 20 is functionally isolated from the blade server 10.

In conclusion, the invention provides a modularized circuit board bus connection control method and system for use with a computer platform, such as a blade server, for providing the blade server with a modularized circuit board bus connection control function; and which is characterized by the capability of fetching an enable signal activating voltage from a built-in enablement setting circuit in the blade server for controlling the connection and disconnection of a bus used to interconnect the server module with the blade server, such that if the server module is well electrically connected to the blade server, the bus will be switched to a connected state to functionally link the server module to the blade server; and otherwise, if poorly connected, the bus will be maintained in the disconnected state such that the server module is functionally isolated from the blade server. This feature can help prevent the chassis management unit of the blade server to waste much time and system resource in the handling of the condition of poor electrical connection and thus to ensure the overall system performance of the blade server. The invention is therefore more advantageous to use than the prior art.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A modularized circuit board bus connection control method for use on a computer platform that can be connected to at least one modularized circuit board via a bus for providing the bus with a connection control function, which comprises:
in an event of the modularized circuit board being plugged to the computer platform, detecting whether a built-in enablement setting circuit in the computer platform has set an enablement signal to true value in response to the condition that the plugging of the modularized circuit board to the computer platform has established an electrical coupling therebetween; and if YES, capable of issuing a link enable message; and
responding to the link enable message by switching the bus into a connected state for functionally linking the modularized circuit board to the computer platform.

2. The modularized circuit board bus connection control method of claim 1, wherein the computer platform is a blade server.

3. The modularized circuit board bus connection control method of claim 1, wherein the blade server is an ATCA (Advanced Telecom Computing Architecture) compliant server system.

4. The modularized circuit board bus connection control method of claim 1, wherein the bus is based on an I2C (Inter-Integrated Circuit) compliant bus architecture.

5. A modularized circuit board bus connection control system for use with a computer platform that can be connected to at least one modularized circuit board via a bus for providing the bus with a connection control function, which comprises:
a detection module, which is capable of being activated in response to an event of the modularized circuit board being plugged to the computer platform, and which is capable of detecting whether a built-in enablement setting circuit in the computer platform has set an enablement signal to true value in the condition that the plugging of the modularized circuit board to the computer platform has established an electrical coupling therebetween; and if YES, capable of issuing a link enable message; and
a switching module, which is connected at a breakpoint in the bus used to interconnect the modularized circuit board with the computer platform, and which is initially set to disconnect the bus and capable of responding to the link enable message from the detection module by switching the bus into a connected state for functionally linking the modularized circuit board to the computer platform.

6. The modularized circuit board bus connection control system of claim 5, wherein the computer platform is a blade server.

7. The modularized circuit board bus connection control system of claim 6, wherein the blade server is an ATCA (Advanced Telecom Computing Architecture) compliant server system.

8. The modularized circuit board bus connection control system of claim 5, wherein the bus is based on an I2C (Inter-Integrated Circuit) compliant bus architecture.

9. The modularized circuit board bus connection control system of claim 5, wherein the detection module is a relay.

10. The modularized circuit board bus connection control system of claim 5, wherein the switching module is a transmission gate device.
